(19) United States
(12) Patent Application Publication
(10) Pub. No.: US 2015/0316694 A1
(43) Pub. Date: Nov. 5, 2015

(54) Reflective Filter, Manufacture Method Thereof, and Display Device

(71) Applicants: BOE Technology Group Co., Ltd., Beijing (CN); Beijing BOE Display Technology Co., Ltd., Beijing (CN)

(72) Inventors: Jun Wu, Beijing (CN); Hongming Zhan, Beijing (CN); Chao Tian, Beijing (CN)

(21) Appl. No.: 14/649,866

(22) PCT Filed: Sep. 2, 2014
(86) PCT No.: PCT/CN2014/085730

§ 371 Date: Jun. 4, 2015

(30) Foreign Application Priority Data
Sep. 17, 2013 (CN) 201310425554.1

(51) Int. Cl. G02B 5/26; C23C 14/34; G02F 1/1335; G02B 1/00; G02B 5/20

(52) U.S. Cl. CPC G02B 5/26; G02B 1/005; G02B 5/201; G02F 1/133514; C23C 14/34

(57) ABSTRACT

Disclosed are a reflective filter, a manufacture method of the reflective filter and a display device utilizing the reflective filter. The reflective filter includes a photonic crystal layer configured to reflect light at a specific waveband. By utilizing different types of photonic crystal regions in the photonic crystal layer to reflect light at different wavebands, it substantially increases the reflectivity of the reflective filter with respect to the ambient light and hence improves the contrast ratio of the display device.

### TECHNICAL FILED

Embodiments of the present invention relate to a reflective filter, a manufacture method of the reflective filter, and a display device utilizing the reflective filter.

### BACKGROUND

Flat plate display device is advantageous in its reduced thickness and weight, low driving voltage, free flicker and long service life etc., as compared with cathode-ray tube display devices. The flat plate display device can be classified into active light-emitting display device and passive light-emitting display device. For example, Thin Film Transistor-Liquid Crystal Display (TFT-LCD) just belongs to the passive light-emitting display device. TFT-LCD is widely used in electronic products including TV set, mobile phone and display device etc., for its advantageous such as stable display quality, realistic image, radiation-free as well as space and energy saving, and hence has dominated the field of two-dimensional display.

Liquid Crystal Device (LCD) can be classified into transmissive display device, transmissive-reflective display device and reflective display device. A display panel of the reflective display device is provided with a reflective plate at its backside, so that the incident ambient light is reflected by the reflective plate and then exits from a pixel region to realize displaying. Compared with the transmissive display device and the transmissive-reflective display device, the reflective display device can fully utilize the ambient light around as an illumination source for image display without the need of backlight modules, and hence obtains better effect of energy saving and environmental protection. For example, in outdoors or in an office with enough sunlight, it's usually preferred to arrange the reflective display device.

The quality of image as displayed by the reflective display device is closely related to the brightness of light reflected by a reflective filter; that is, the brighter the ambient light is, the higher the reflectivity of the reflective plate in the reflective display device with regard to the ambient light will be, which also leads to increased contrast ratio and more distinct image as displayed by the display device. However, at the same time of reflecting the ambient light, the reflective plate also absorbs considerable part of light, which results in a reduced reflectivity of the reflective display device with respect to the ambient light and a degraded contrast ratio thereof, etc.

### SUMMARY

Embodiments of the present invention provide a reflective filter which can improve a reflectivity with respect to the ambient light; further, embodiments of the present invention further provide a manufacture method of the reflective filter and a display device utilizing the reflective filter.

At least one embodiment of the present invention provides a reflective filter comprising a photonic crystal layer configured to reflect light at a specific waveband.

For example, in an embodiment of the present invention, the photonic crystal layer comprises a first photonic crystal region configured to reflect light at a first waveband, a second photonic crystal region configured to reflect light at a second waveband, and a third photonic crystal region configured to reflect light at a third waveband; a plurality of the first photonic crystal regions, the second photonic crystal regions and the third photonic crystal regions are arranged alternately to form an array structure.

For example, in an embodiment of the present invention, the light at a first waveband is red light, the light at a second waveband is green light, and the light at a third waveband is blue light.

For example, in an embodiment of the present invention, the photonic crystal layer has an opal-like structure; the photonic crystal layer is consisted of a matrix material having a first refractivity and a dielectric material having a second refractivity periodically formed in the matrix material.

For example, in an embodiment of the present invention, the reflective filter further comprises a protective layer disposed on a light incident side and/or a transmitted-light exiting side of the photonic crystal layer.

For example, in an embodiment of the present invention, the reflective filter further comprises a substrate; the photonic crystal layer is disposed on the substrate.

For example, in an embodiment of the present invention, the matrix material having a first refractivity is air, and the dielectric material having a second refractivity periodically formed in the matrix material is monodisperse microsphere.

For example, in an embodiment of the present invention, for the photonic crystal layer configured to reflect light at a waveband having a central wavelength of λ, the monodisperse microsphere has a radius of

$$R = \frac{λ}{2 n \cdot cos ( θ ) \cdot c} ;$$

wherein n denotes an effective refractivity of the photonic crystal layer, θ denotes an included angle between the incident light and a normal of the photonic crystal layer, c denotes a constant related to a manufacture method of the photonic crystal layer.

For example, in an embodiment of the present invention, the monodisperse microsphere comprises one or more of polystyrene microsphere, polymethyl methacrylate microsphere and silicon dioxide microsphere.

For example, in an embodiment of the present invention, the photonic crystal layer comprises multiple layers of the monodisperse microsphere.

For example, in an embodiment of the present invention, the number of layers of the monodisperse microsphere is no less than 10.

Another embodiment of the present invention further provides a manufacture method of reflective filter, comprising: forming a photonic crystal layer configured to reflect light at a specific waveband.

For example, in an embodiment of the present invention, forming a photonic crystal layer configured to reflect light at a specific waveband comprises: forming a first photonic crystal region configured to reflect light at a first waveband, a second photonic crystal region configured to reflect light at a second waveband and a third photonic crystal region configured to reflect light at a third waveband on a substrate; a plurality of the first photonic crystal regions, the second photonic crystal regions and the third photonic crystal regions are arranged alternately to form an array structure.

For example, in an embodiment of the present invention, forming the photonic crystal layer by way of self-assembly.

For example, in an embodiment of the present invention, the method comprises: preparing a solution containing monodisperse microsphere material; and forming a photonic crystal layer on a substrate by one or more of quasi-equilibrium evaporation method, gravitational method, spin-coating method and sputtering deposition method.

Yet another embodiment of the present invention further provides a display device comprising any one of the above reflective filters.

For example, in an embodiment of the present invention, the display device further comprises a light absorption unit, the light absorption unit is located at a transmitted-light exiting side of the reflective filter and configured to absorb light transmitting through the reflective filter.

For example, in an embodiment of the present invention, the absorption unit is a protective layer disposed at a transmitted-light exiting side of the photonic crystal layer; or, the photonic crystal layer is disposed on a substrate, and the light absorption unit serves as the substrate.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a sectional view illustrating a structure of a reflective filter according to an embodiment of the present invention;

FIG. 2 is a top view illustrating a structure of a reflective filter according to an embodiment of the present invention;

FIG. 3 is a sectional view illustrating a structure of a display device according to an embodiment of the present invention.

### DETAILED DESCRIPTION OF THE PREFERRED EMBODIMENTS

In order to make objects, technical details and advantages of the embodiments of the invention apparent, technical solutions according to the embodiments of the present invention will be described clearly and completely as below in conjunction with the accompanying drawings of embodiments of the present invention. It is to be understood that the described embodiments are only a part of but not all of exemplary embodiments of the present invention. Based on the described embodiments of the present invention, various other embodiments can be obtained by those of ordinary skill in the art without creative labor and those embodiments shall fall into the protection scope of the present invention.

Photonic Crystal (PC for short) is a kind of newly developing optical material. Since photonic crystal material has a crystalline structure with periodically repeated refractivity, the Bragg scatter light propagating in the photonic crystal material will be subjected to optical modulation and hence form an energy band structure which generates photonic band gap (PBG for short) having a strong reflection peak at its center; as a result, the photonic crystal material has a reflectivity of approximate 100% with respect to the light at the waveband of the photonic band gap. The reflective filter and the reflective display device as provided by embodiments of the present invention utilize the photonic crystal. Hereafter the reflective filter, the manufacture method of reflective filter and the reflective display device according to embodiments of the present invention are described in details with reference to particular implementations.

An embodiment of the present invention provides a reflective filter comprising a photonic crystal layer configured to reflect light at a specific waveband. For example, the reflective filter can reflect light at different wavebands by utilizing photonic crystal regions of the photonic crystal layer having different photonic band gaps. Since specific photonic crystal material almost can completely reflect the light at a specific waveband without any absorption, the reflectivity of the reflective filter with respect to the ambient light can be substantially increased so as to improve the contrast ratio of the display device, which allows more distinct image as displayed by the display device and thus enhances customer experience.

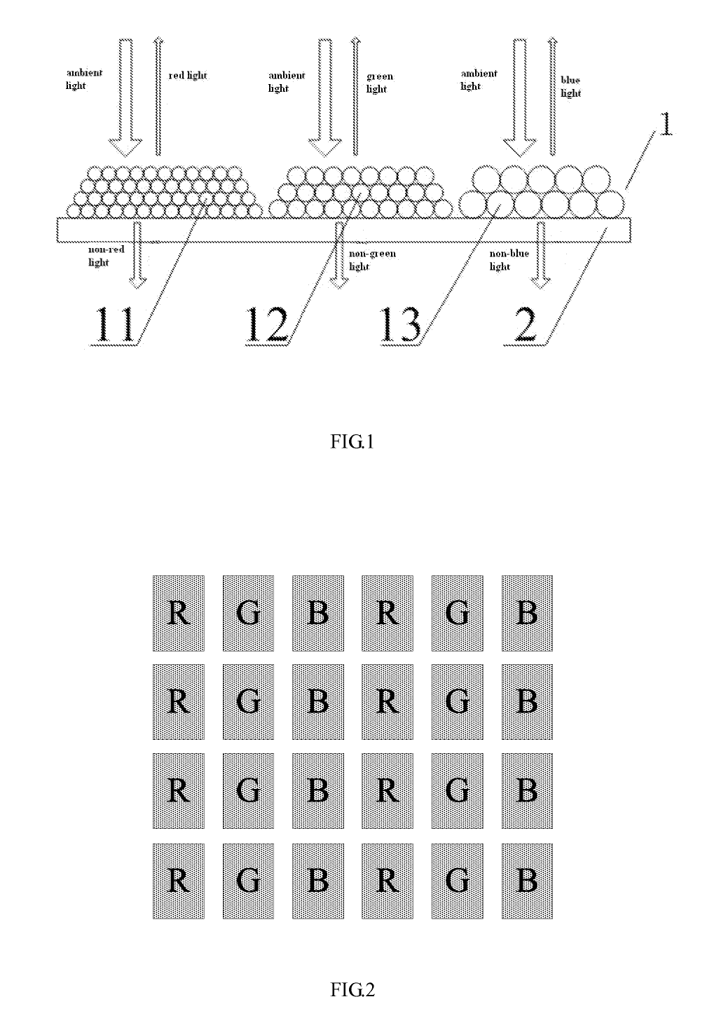

FIG. 1 is a sectional view illustrating a structure of a reflective filter as provided by an embodiment of the present invention. The reflective filter 1 comprises a photonic crystal layer configured to reflect light at a specific waveband and a substrate 2; the photonic crystal layer is disposed on the substrate 2. The reflective filter as provided by embodiments of the present invention may not comprise the substrate. The photonic crystal layer of the reflective filter 1 comprises three types of photonic crystal regions which are a first photonic crystal region 11 configured to reflect light at a first waveband, a second photonic crystal region 12 configured to reflect light at a second waveband and a third photonic crystal region 13 configured to reflect light at a third waveband. A plurality of the first photonic crystal regions 11, the second photonic crystal regions 12 and the third photonic crystal regions 13 are arranged alternately to form an array as shown in FIG. 2.

For example, the photonic crystal layer in the present embodiment is configured to reflect normally used RGB (red, green and blue) lights; that is, the above-mentioned light at the first waveband refers to the red light, the above-mentioned light at the second waveband refers to the green light, and the above-mentioned light at the third waveband refers to the blue light. The light at other wavebands such as CMY (cyan, magenta and yellow) light may also be reflected by the photonic crystal layer. The photonic crystal layer can also be configured to reflect light at four or more types of wavebands. For example, the reflective filter as provided by embodiments of the present invention can be configured to reflect four-color light such as RGBK (red, green, blue and dark) light and CMYK (cyan, magenta, yellow and black) light, and hence can be applied in RGBK (red, green, blue and dark) display and CMYK (cyan, magenta, yellow and black) display, respectively, without limiting to the ones listed in embodiments of the present invention.

The photonic crystal layer in embodiments of the present invention consists of a matrix material having a first refractivity and a dielectric material having a second refractivity formed in the matrix material. For example, two of the common photonic crystalline structures are opal-like structure and inverse opal structure. Opal-like photonic crystal, also referred to as artificial opal, has a cubic close packed structure similar with natural opal. The opal-like photonic crystal consists of a matrix material having a first refractivity and a dielectric material having a second refractivity periodically formed in the matrix material; the matrix material is air, for example, and the dielectric material may be monodisperse microsphere such as polystyrene (PS for short) microsphere, polymethylmethacrylate (PMMA for short) microsphere or silicon dioxide (SiO₂) microsphere.

In an embodiment of the present invention, it's usually preferred to use air as the above-mentioned matrix material in the opal-like photonic crystal, in order to simplify the manufacture process.

Such kind of opal-like structure can serve as a pattern plate which is removed after filling inorganic materials having relatively higher refractivity within gaps of the microspheres so as to obtain a photonic crystal with inverse opal structure. Since the manufacture of the photonic crystal with inverse opal structure needs to use the pattern plate with opal-like structure, the precision for “copying” the structure depends on various factors including, for example, Van der Waals interaction, the wettability at a surface of the pattern plate, the filling situation at gaps of the pattern plate, and the volume shrinkage of the matrix during curing process etc., and minor changes in any of these factors may lead to defects in the inverse opal structure and usually results in a disorder of the structure, which all severally influence the optical performance of the photonic crystal. Therefore, the photonic crystal layer in embodiments of the present invention preferably comprises the above-mentioned photonic crystal having opal-like structure.

In an embodiment of the present invention, the photonic crystal layer is formed by stacking multiple layers of monodisperse microspheres. The monodisperse microsphere may be any one or more of polystyrene microsphere, polymethyl methacrylate microsphere and silicon dioxide microsphere, for example. Generally speaking, in case of more than 10 layers of monodisperse microspheres, it will be presenting an obvious photonic crystal performance. Moreover, the larger the number of layers of monodisperse microsphere is, the higher the reflective efficiency of the photonic crystal layer will be. Therefore, the number of layers of monodisperse microsphere in embodiments of the present invention is no less than 10, without a specified upper limit.

For the opal-like photonic crystal, a central wavelength of the photonic band gap thereof may be calculated precisely according to the Bragg scattering formula; that is, the central wavelength of the photonic band gap is calculated from λ=2nd cos(θ), wherein d denotes an interplanar distance in a face-centered cubic lattice, θ denotes an included angle between a vector of the incident light and a normal of the photonic crystal. For example, for the photonic crystal formed of polystyrene microsphere, n denotes an effective refractivity of the photonic crystal layer, that is, the refractivity of the entire photonic crystal layer. For example, in an embodiment in which the photonic crystal is formed of the polystyrene microsphere, n=\sqrt{n_{PS}²×74%+nₐᵢᵣ²×26%}, where n_{PS} denotes a refractivity of polystyrene and n_{PS}=1.59, nₐᵢᵣ denotes a refractivity of air and nₐᵢᵣ=1, d=1.633R, R denotes a radius of the polystyrene microsphere, and θ is aero in case of vertically incident light. Therefore, it's possible to precisely control the central wavelength of the photonic band gap by adjusting a grain size of the monodisperse microsphere so as to realize reflecting light at a specific waveband. Moreover, the reflection spectrum of the photonic crystal layer is extremely narrow because of the reflective action of the photonic band gap and the integral property of the photonic crystal. In other words, if the photonic crystal involves no defect, the light reflected by the photonic band gap will become monochromatic light. It's known that most display devices have difficulty in generating monochromatic light, which makes it difficult to further improve a color gamut of the display device. However, in embodiments of the present invention, almost all the light reflected by the photonic band gap becomes monochromatic light, thus it can expand the color gamut of the display device to a large extent; that is to say, it will be easier to achieve displaying with wider color gamut.

The grain size of the monodisperse microsphere may be obtained by reversely deducing from the Bragg scattering formula above; that is, for the photonic crystal layer configured to reflect light at a waveband having a central wavelength of λ, the monodisperse microsphere forming the photonic crystal layer has a radius of

$$R = \frac{λ}{2 n \cdot cos ( θ ) \cdot c} ,$$

wherein n denotes an effective refractivity of the photonic crystal layer, θ denotes an included angle between the incident light and a normal of the photonic crystal layer, c denotes a constant related to a manufacture method of the photonic crystal layer.

For example, concerning the RGB tricolor as defined by CIE 1931 (standards stipulated by the Committee of International Illumination in 1931) in which a wavelength of the red light is 700.0 nm, a wavelength of the green light is 546.1 nm and a wavelength of the blue light is 435.8 nm, it can be seen from calculation that the photonic crystal formed of polystyrene microsphere will reflect the red light when the polystyrene microsphere has a grain size (diameter) of 293.7 nm, will reflect the green light when the polystyrene microsphere has a grain size of 229.1 nm and will reflect the blue light when the polystyrene microsphere has a grain size of 182.8 nm. In case that the silicon dioxide microsphere is used for replacing the polystyrene microsphere, the effective refractivity of the photonic crystal is changed as 1.45 and it can be seen from calculation that the photonic crystal formed of silicon dioxide microsphere will reflect the red light when the silicon dioxide microsphere has a grain size of 318.1 nm, will reflect the green light when the silicon dioxide microsphere has a grain size of 248.2 nm and will reflect the blue light when the silicon dioxide microsphere has a grain size of 198 nm, etc.

In order to prevent the structure of the photonic crystal layer from external damages which may adversely influence the optical property thereof, an embodiment of the present invention further provides the photonic crystal layer with a protective layer. The protective layer may be disposed on both of a light incident side and a transmitted-light exiting side of the photonic crystal layer; or, may be disposed on either the light incident side or the transmitted-light exiting side of the photonic crystal layer. In an embodiment of the present invention, the photonic crystal layer is disposed on a substrate; that is, the transmitted-light exiting side of the photonic crystal layer is in direct contact with the substrate, thus the substrate also serves as a protective layer.

An embodiment of the present invention further provides a manufacture method of the reflective filter as described in any of the above embodiments, comprising: forming a photonic crystal layer configured to reflect light at a specific waveband. For example, the manufacture method of reflective filter as provided by an embodiment of the present invention further comprises a step of providing a substrate 2. For example, forming a photonic crystal layer configured to reflect light at a specific waveband comprises: forming a first photonic crystal region 11 configured to reflect light at a first waveband, a second photonic crystal region 12 configured to reflect light at a second waveband and a third photonic crystal region 13 configured to reflect light at a third waveband on the substrate 2; a plurality of the first photonic crystal regions 11, the second photonic crystal regions 12 and the third photonic crystal regions 13 are arranged alternately to form an array. In the manufacture method, parameters like the material and thickness of the photonic crystal layer and the grain size of the monodisperse microsphere, etc. are set according to the above-mentioned reflective filter, and details thereof will be omitted herein.

For example, the photonic crystal layer in embodiments of the present invention may be formed by different ways of self-assembly. For example, the method comprises steps as below.

Firstly, preparing a solution mixed with monodisperse microsphere material.

For example, mixing the monodisperse microsphere material (for example, polystyrene microsphere, polymethyl methacrylate microsphere and silicon dioxide microsphere) into a mixture solution of ethanol and water so as to obtain a solution mixed with the monodisperse microsphere material.

Afterwards, forming a photonic crystal layer on the substrate 2 by one or more methods selected from self-assembly methods including quasi-equilibrium evaporation method, gravitational method, spin-coating method and sputtering deposition method.

For example, in the quasi-equilibrium evaporation method, the solution mixed with monodisperse microsphere material is evaporated naturally and then self-assembled by utilizing a surface tension of the solution, so as to obtain the photonic crystals. For another example, in the gravitational method, an opal-like structure is spontaneously formed by using the monodisperse microsphere material under the effect of gravitational field, so as to obtain the photonic crystals. For yet another example, in the spin-coating method, the monodisperse microsphere material initiates an ordered, self-assemble process driven by the effect of centrifugal force.

Of course, the photonic crystal in embodiments of the present invention may also be formed by other ways. For example, the photonic crystal may be formed by utilizing an exposure technology through mixing a small amount of photoresists in the monodisperse microsphere material, coating the mixture onto the substrate 2 and then performing exposure and development thereto. Alternatively, physical methods such as micromachined method and hole-drilling method may be utilized. For another example, corrosion method, stacking layer-by-layer method, two-photon photopolymerization method and holographic printing method may also be utilized.

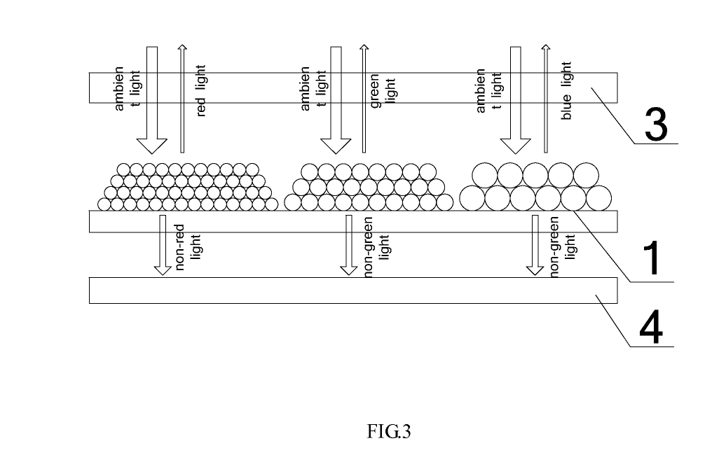

An embodiment of the present invention further provides a display device as shown in FIG. 3. The display device comprises a display panel 3 and the reflective filter 1 as described in any of the above embodiments, wherein the display panel 3 is located at a light incident side of the reflective filter. Of course, the reflective filter may also be utilized to manufacture a color filter substrate which is to be assembled with an array substrate into a cell to form the display panel. For example, the photonic crystal layer disposed on the reflective filter 1 comprises multiple types of photonic crystal regions configured to reflect light at different wavebands. For example, the ambient light incident on the display panel 3 is reflected by the first photonic crystal region 11, the second photonic crystal region 12 and the third photonic crystal region 13, respectively, and becomes the red light, the green light and the blue light; then the reflected light is modulated by the display panel 3 according to the image information so as to achieve image display. For example, the display panel 3 may be LCD panel, electrophoretic display panel, electrowetting display panel or electrochromic display panel, etc.

Additionally, the display device as provided by embodiments of the present invention may further comprise a light absorption unit 4; the light absorption unit 4 is located at a transmitted-light exiting side of the reflective filter 1 and configured to absorb the light transmitting through the reflective filter 1, so as to avoid any adverse influence on the image display caused by the light being reflected. For example, when a protective layer is disposed at the transmitted-light exiting side of the photonic crystal layer, it can be configured as a light absorption unit; and when the photonic crystal layer is directly disposed on the substrate, the substrate can also serve as a light absorption unit.

Since specific photonic crystal material almost can completely reflect light at a specific waveband without any absorption, the reflectivity of the display device with respect to the ambient light can be substantially increased so as to improve the contrast ratio of the display device, which allows more distinct image as displayed by the display device and thus enhances customer experience.

It is understood that the described above are just exemplary implementations and embodiments to explain the principle of the present invention and the invention is not intended to limit thereto. An ordinary person in the art can make various variations and modifications to the present invention without departure from the spirit and the scope of the present invention, and such variations and modifications shall fall in the scope of the present invention.

The present application claims the priority of China patent application No. 201310425554.1 filed on Sep. 17, 2013, which is incorporated herein by reference in its entirely.

1. A reflective filter, comprising a photonic crystal layer configured to reflect light at a specific waveband.

2. The reflective filter of claim 1, wherein the photonic crystal layer comprises a first photonic crystal region configured to reflect light at a first waveband, a second photonic crystal region configured to reflect light at a second waveband and a third photonic crystal region configured to reflect light at a third waveband; a plurality of the first photonic crystal regions, the second photonic crystal regions and the third photonic crystal regions are arranged alternately to form an array structure.

3. The reflective filter of claim 2, wherein the light at a first waveband is red light, the light at a second waveband is green light, and the light at a third waveband is blue light.

4. The reflective filter of claim 1, wherein the photonic crystal layer has an opal-like structure; the photonic crystal layer comprises a matrix material having a first refractivity and a dielectric material having a second refractivity periodically formed in the matrix material.

5. The reflective filter of claim 1, further comprising a protective layer, wherein the protective layer is disposed on a light incident side and/or a transmitted-light exiting side of the photonic crystal layer.

6. The reflective filter of claim 1, further comprising a substrate, wherein the photonic crystal layer is disposed on the substrate.

7. The reflective filter of claim 4, wherein the matrix material having a first refractivity is air, and the dielectric material having a second refractivity periodically formed in the matrix material is monodisperse microsphere.

8. The reflective filter of claim 7, wherein for the photonic crystal layer configured to reflect light at a waveband with a central wavelength of λ, the monodisperse microsphere sphere has a radius of
$$R = \frac{λ}{2 n \cdot cos ( θ ) \cdot c} ,$$
wherein n denotes an effective refractivity of the photonic crystal layer, θ denotes an included angle between incident light and a normal of the photonic crystal layer, c denotes a constant related to a method for manufacturing the photonic crystal layer.

9. The reflective filter of claim 7, wherein the monodisperse microsphere comprises one or more of polystyrene microsphere, polymethyl methacrylate microsphere and silicon dioxide microsphere.

10. The reflective filter of claim 7, wherein the photonic crystal layer comprises multiple layers of the monodisperse microsphere.

11. The reflective filter of claim 10, wherein the number of layers of the monodisperse microsphere is equal to or greater than 10.

12. A method for manufacturing a reflective filter, comprising: forming a photonic crystal layer configured to reflect light at a specific waveband.

13. The method of claim 12, wherein forming a photonic crystal layer configured to reflect light at a specific waveband comprises:
forming a first photonic crystal region configured to reflect light at a first waveband, a second photonic crystal region configured to reflect light at a second waveband and a third photonic crystal region configured to reflect light at a third waveband on a substrate; a plurality of the first photonic crystal regions, the second photonic crystal regions and the third photonic crystal regions are arranged alternately to form an array structure.

14. The method of claim 12, wherein forming the photonic crystal layer by way of self-assembly.

15. The method of claim 14, comprising:
preparing a solution containing monodisperse microsphere material; and
forming the photonic crystal layer on the substrate by one or more of a quasi-equilibrium evaporation method, a gravitational method, a spin-coating method and a sputtering deposition method.

16. A display device, comprising the reflective filter of claim 1.

17. The display device of claim 16, further comprising a light absorption unit, wherein the light absorption unit is located at a transmitted-light exiting side of the reflective filter and configured to absorb light transmitting through the reflective filter.

18. The display device of claim 17, wherein the light absorption unit is a protective layer disposed at the transmitted-light exiting side of the photonic crystal layer; or, the photonic crystal layer is disposed on the substrate, and the light absorption unit serves as the substrate.

19. The reflective filter of claim 8, wherein the photonic crystal layer comprises multiple layers of the monodisperse microsphere.

20. The reflective filter of claim 9, wherein the photonic crystal layer comprises multiple layers of the monodisperse microsphere.
